(19) United States
(12) Patent Application Publication
(10) Pub. No.: US 2026/0170192 A1
(43) Pub. Date: Jun. 18, 2026

(54) METHOD AND DEVICE FOR GENERATING VEHICLE OBJECT MODELS

(71) Applicants: Hyundai Motor Company, Seoul (KR); Kia Corporation, Seoul (KR)

(72) Inventor: Joahun KIM, Hwaseong-Si (KR)

(21) Appl. No.: 19/394,387

(22) Filed: Nov. 19, 2025

(30) Foreign Application Priority Data
Dec. 13, 2024 (KR) 10-2024-0185617

(51) Int. Cl. G06F 30/15

(52) U.S. Cl. CPC G06F 30/15

(57) ABSTRACT

A method and device for generating a vehicle object model is provided. The method may include: obtaining a three-dimensional vehicle object model including a plurality of components of a vehicle; determining, based on the three-dimensional vehicle object model and physical attributes of the plurality of components: a first level vehicle object model by applying first physical property data of a first material to at least one component of the plurality of components of the three-dimensional vehicle object model; and a second level vehicle object model by applying second physical property data of a second material, that is different from the first material, to the at least one component; and performing, on at least one of the first level vehicle object model or the second level vehicle object model, an electromagnetic wave simulation to determine a level of physical attributes to be applied to the three-dimensional vehicle object model.

### CROSS-REFERENCE TO RELATED APPLICATION

This application claims priority to and the benefit of Korean Patent Application No. 10-2024-0185617, filed in the Korean Intellectual Property Office on Dec. 13, 2024, the entire contents of which are incorporated herein by reference.

### TECHNICAL FIELD

The present disclosure relates to vehicle simulation, and more particularly to a method and device for generating a vehicle object model.

### BACKGROUND

To develop and verify a new autonomous driving technology, various scenarios that may occur in actual road environments may be evaluated. For this purpose, actual (e.g., real-life) vehicle tests may be used, but the more time and cost may be required to build an actual vehicle testing environment increase. Other limitations of real-life testing may include difficulties of evaluating rare situations, also referred to as corner cases. To complement these limitations, a virtual vehicle simulation environment may be utilized. Simulation tool chain suppliers may, for example, provide various functions to support the development and verification of autonomous driving technology, and may generate surrounding environment data such as roads and objects required for implementing autonomous driving functions through virtual vehicles and sensor models. This allows for evaluation of various scenarios including corner cases.

The matters described in this Background section are only for enhancement of understanding of the background of the disclosure, and should not be taken as acknowledgement that they correspond to prior art already known to those skilled in the art.

### SUMMARY

The present disclosure attempts to provide a method and device for generating a vehicle object model for ensuring consistency between various simulation tool chains and sensor models, and allowing estimation with high reliability for the scenarios including a corner case.

According to one or more example embodiments of the present disclosure, a device may include: a processor; and a memory storing a three-dimensional vehicle object model of a vehicle. The three-dimensional vehicle object model may include a plurality of components of the vehicle. The memory may further store at least one instruction that is configured, when executed by the processor communicating with the memory, to cause the device to: obtain, from the memory, the three-dimensional vehicle object model; determine, based on the three-dimensional vehicle object model and physical attributes of the plurality of components: a first level vehicle object model by applying first physical property data of a first material to at least one component of the plurality of components of the three-dimensional vehicle object model; and a second level vehicle object model by applying second physical property data of a second material, that is different from the first material, to the at least one component; and perform, on at least one of the first level vehicle object model or the second level vehicle object model, an electromagnetic wave simulation to determine a level of physical attributes to be applied to the three-dimensional vehicle object model.

The at least one instruction may be configured, when executed by the processor communicating with the memory, to cause the device to perform the electromagnetic wave simulation by: obtaining, based on performing the electromagnetic wave simulation on the first level vehicle object model, a first radar cross section (RCS) map associated with the vehicle; and obtaining, based on performing the electromagnetic wave simulation on the second level vehicle object model, a second RCS map associated with the vehicle. The at least one instruction may be configured, when executed by the processor communicating with the memory, to further cause the device to determine the level of physical attributes based on a comparison between the first RCS map and the second RCS map.

The at least one instruction may be configured, when executed by the processor communicating with the memory, to further cause the device to perform the comparison by: determining an absolute difference between the first RCS map and the second RCS map; performing a correlation analysis on each of the first RCS map and the second RCS map; and determining, based on the absolute difference and the correlation analysis, a correlation value of the first RCS map and the second RCS map.

The at least one instruction may be configured, when executed by the processor communicating with the memory, to further cause the device to determine the level of physical attributes by: selecting, based on the correlation value being greater than or equal to a threshold value, a level associated with the first level vehicle object model corresponding to the first RCS map.

The at least one instruction may be configured, when executed by the processor communicating with the memory, to further cause the device to determine the level of physical attributes by: selecting, based on the correlation value being less than a threshold value, a level associated with the second level vehicle object model corresponding to the second RCS map.

The at least one instruction may be configured, when executed by the processor communicating with the memory, to cause the device to perform the electromagnetic wave simulation by: determining, based on a first recognition time by a radar sensor on the first level vehicle object model, a first recognition performance value; determining, based on a second recognition time by the radar sensor on the second level vehicle object model, a second recognition performance value; and verifying, based on a comparison between the first recognition performance value and the second recognition performance value, validity of the determined level of physical attributes.

The at least one instruction may be configured, when executed by the processor communicating with the memory, to cause the device to verify the validity by: determining, based on a mean absolute difference between the first recognition performance value and the second recognition performance value being less than or equal to a threshold value, that the determined level of physical attributes is valid.

The at least one instruction may be configured, when executed by the processor communicating with the memory, to cause the device to verify the validity by: determining, based on a mean absolute difference between the first recognition performance value and the second recognition performance value being greater than a threshold value, that the determined level of physical attributes is valid.

The plurality of components may include at least one of a body, a wheel, a lamp, a bumper, and a windshield.

According to one or more example embodiments of the present disclosure, a method performed by a computing device may include: obtaining, by a processor of the computing device, a three-dimensional vehicle object model of a vehicle. The three-dimensional vehicle object model may include a plurality of components of the vehicle. The method may further include: determining, based on the three-dimensional vehicle object model and physical attributes of the plurality of components: a first level vehicle object model by applying first physical property data of a first material to at least one component of the plurality of components of the three-dimensional vehicle object model; and a second level vehicle object model by applying second physical property data of a second material, that is different from the first material, to the at least one component; and performing, on at least one of the first level vehicle object model or the second level vehicle object model, an electromagnetic wave simulation to determine a level of physical attributes to be applied to the three-dimensional vehicle object model.

Performing the electromagnetic wave simulation may include: obtaining, based on performing the electromagnetic wave simulation on the first level vehicle object model, a first radar cross section (RCS) map associated with the vehicle; and obtaining, based on performing the electromagnetic wave simulation on the second level vehicle object model, a second RCS map associated with the vehicle. The method may further include: determining the level of physical attributes based on a comparison between the first RCS map and the second RCS map.

The method may further include performing the comparison by: determining an absolute difference between the first RCS map and the second RCS map;
performing a correlation analysis on each of the first RCS map and the second RCS map; and determining, based on the absolute difference and the correlation analysis, a correlation value of the first RCS map and the second RCS map.

The method may further include: selecting, based on the correlation value being greater than or equal to a threshold value, a level associated with the first level vehicle object model corresponding to the first RCS map.

The method may further include: selecting, based on the correlation value being less than a threshold value, a level associated with the second level vehicle object model corresponding to the second RCS map.

Performing the electromagnetic wave simulation may include: determining, based on a first recognition time by a radar sensor on the first level vehicle object model, a first recognition performance value; determining, based on a second recognition time by the radar sensor on the second level vehicle object model, a second recognition performance value; and verifying, based on a comparison between the first recognition performance value and the second recognition performance value, validity of the determined level of physical attributes.

Verifying the validity may include: determining, based on a mean absolute difference between the first recognition performance value and the second recognition performance value being less than or equal to a threshold value, that the determined level of physical attributes is valid.

Verifying the validity may include: determining, based on a mean absolute difference between the first recognition performance value and the second recognition performance value being greater than a threshold value, that the determined level of physical attributes is valid.

The plurality of components may include at least one of a body, a wheel, a lamp, a bumper, and a windshield.

The method may further include: performing, based on applying the determined level of physical attributes to the three-dimensional vehicle object model, a simulation on the vehicle.

According to one or more example embodiments of the present disclosure, a non-transitory computer-readable medium may store instructions that, when executed by a computing device, cause the computing device to obtain a three-dimensional vehicle object model of a vehicle. The three-dimensional vehicle object model may include a plurality of components of the vehicle. The instructions, when executed by a computing device, may further cause the computing device to: determine, based on the three-dimensional vehicle object model and physical attributes of the plurality of components: a first level vehicle object model by applying first physical property data of a first material to at least one component of the plurality of components of the three-dimensional vehicle object model; and a second level vehicle object model by applying second physical property data of a second material, that is different from the first material, to the at least one component; and performing, on at least one of the first level vehicle object model or the second level vehicle object model, an electromagnetic wave simulation to determine a level of physical attributes to be applied to the three-dimensional vehicle object model.

### BRIEF DESCRIPTION OF THE DRAWINGS

FIG. 1 shows an example device for generating vehicle object models.

FIG. 2 and FIG. 3 show example vehicle object models.

FIG. 4 shows operations of an example device for generating vehicle object models.

FIG. 5 and FIG. 6 show an example of an RCS map obtained by an example device for generating vehicle object models.

FIG. 7, FIG. 8, and FIG. 9 show operations of an example device for generating vehicle object models.

FIG. 10 shows an example method for generating vehicle object models.

FIG. 11 shows an example method for generating vehicle object models.

FIG. 12 shows an example computing device.

### DETAILED DESCRIPTION

The present disclosure will be described more fully hereinafter with reference to the accompanying drawings, in which one or more example embodiments of the disclosure are shown. As those skilled in the art would realize, the described example embodiment(s) may be modified in various different ways, all without departing from the spirit or scope of the present disclosure. Accordingly, the drawings and description are to be regarded as illustrative in nature and not restrictive, and like reference numerals designate like elements throughout the specification.

Unless explicitly described to the contrary, the word “comprise”, and variations such as “comprises” or “comprising”, will be understood to imply the inclusion of stated elements but not the exclusion of any other elements. Terms including ordinal numbers such as first, second, and the like will be used only to describe various components, and are not to be interpreted as limiting these components. The terms are only used to differentiate one component from other components.

The terms such as “ . . . part,” “ . . . portion,” “ . . . er/or,” or “module” disclosed in the present specification may mean a unit that may process at least one function or operation described in this specification, and this may be implemented by hardware, software, or a combination thereof. At least some components or functions in the method and device for generating a vehicle object model for vehicle simulation according to example embodiment(s) may be implemented as a program or software, and the program or software may be stored in a computer-readable medium.

For purposes of the present application and the claims, using the exemplary phrase “at least one of: A; B; or C” or “at least one of A, B, or C,” the phrase means “at least one A, or at least one B, or at least one C, or any combination of at least one A, at least one B, and at least one C. Further, exemplary phrases, such as “A, B, or C”, “at least one of A, B, and C”, “at least one of A, B, or C”, etc. as used herein may mean each listed item or all possible combinations of the listed items. For example, “at least one of A or B” may refer to (1) at least one A; (2) at least one B; or (3) at least one A and at least one B.

To ensure the reliability of evaluations obtained through virtual simulation environments, a precisely designed sensor model based on the specifications and an object model including physical characteristics may be required. However, the method for defining the physical characteristics of the object model may be different for each simulation tool chain, and, at least in some implementations, there exists a problem of efficiently handling different object models when using different simulation tool chains for each sensor. For this reason, there may be difficulties in ensuring consistency in the simulation environment.

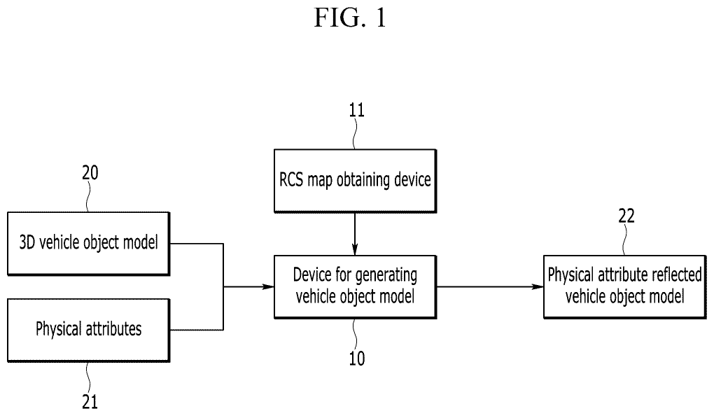

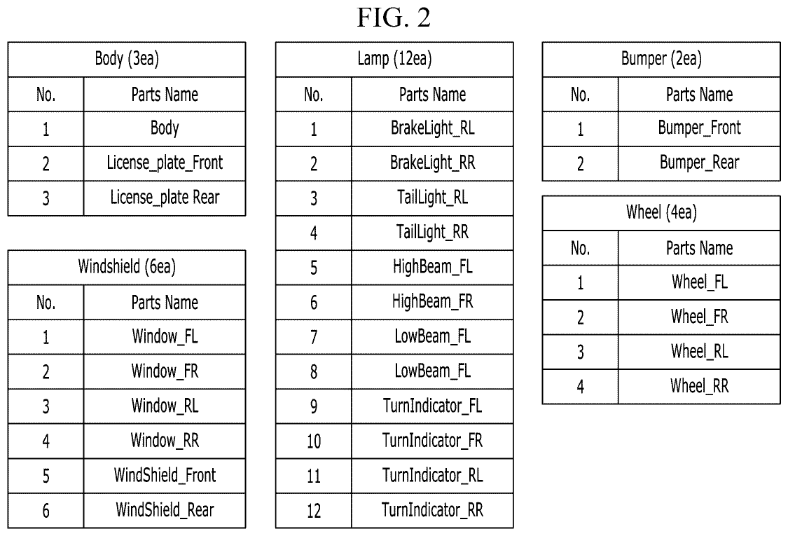

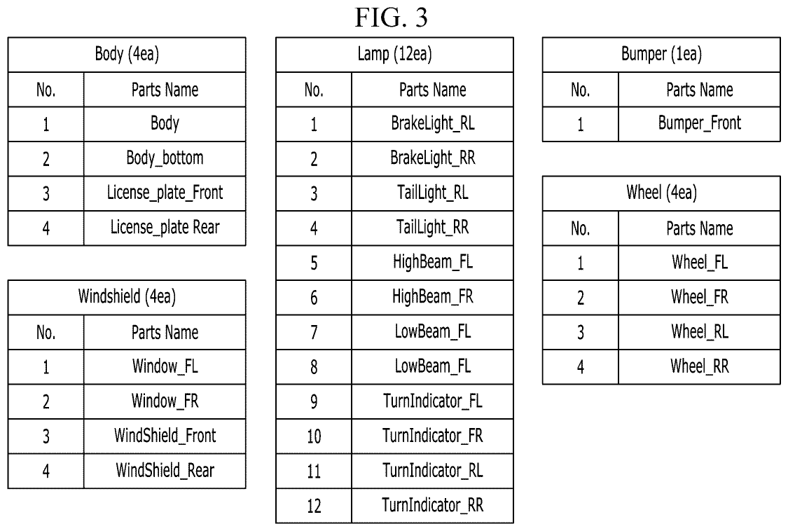

FIG. 1 shows an example device for generating vehicle object models, and FIG. 2 and FIG. 3 show example vehicle object models.

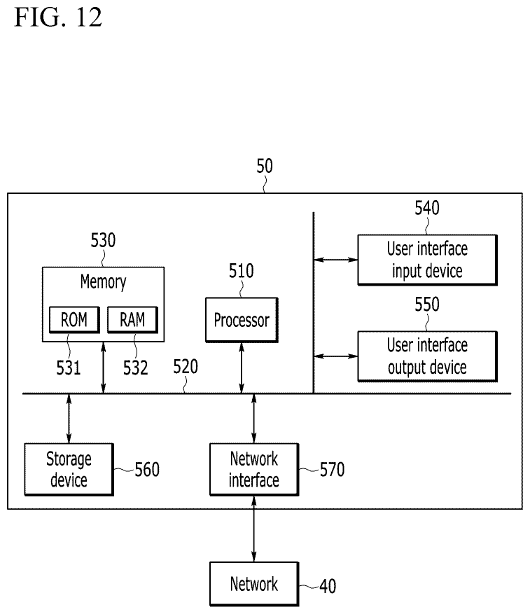

Referring to FIG. 1, the device for generating a vehicle object model 10 may be implemented as a computing device including a processor and a memory. For example, the device for generating a vehicle object model 10 may be implemented as a computing device 50 to be described with reference to FIG. 12. The processor may correspond to a processor 510 of the computing device 50, and the memory may correspond to a memory 520 of the computing device 50. The device for generating a vehicle object model 10 may include at least one non-transitory computer-readable medium including (e.g., storing) instructions and at least one processor for performing operation by executing the instructions. The at least one non-transitory computer-readable medium (e.g., memory) may also store one or more three-dimensional vehicle object models. The operations may include components, functions, stages, etc., described in the present specification, regarding the method and device for generating a vehicle object model.

To develop and verify autonomous driving technology in a virtual vehicle simulation environment, a foundation for generating realistic surrounding environment data is required. The data are generated through interactions between the sensor model and the object model provided by the simulation tool chain. In some implementations, a vehicle object model including physical attributes may be provided for each simulation tool chain, but the model configuration method may be different and there may not be a clear (e.g., unified) reference or standard for the level of detail required to generate a vehicle object model database (DB). In particular, when using different simulation tool chains for respective sensors, it may be difficult to ensure consistency in simulation results due to differences in the way the object models are configured.

The device for generating a vehicle object model 10 may improve this problem by comparing and analyzing object model radar cross-section (RCS) maps at each physical attribute-based detail level to derive the required conditions for generating a vehicle object model DB. An RCS (also referred to as a radar signature) may refer to a unique characteristic of a radar signal that is reflected off an object. An RCS may represent a measure of how detectable the object is by a radar. Since different objects may have different RCS values, an RCS value can be used to uniquely identify a corresponding object. Thus, an RCS of an object may be considered a unique visual identifier or representation (e.g., fingerprint) of that specific object (e.g., a vehicle) when detected by a radar. An RCS map (also referred to as RCS diagram) may be a data map that spatially represents the characteristics of an object reflected by a radar signal (electromagnetic wave). Specifically, an RCS map may be a polar or linear plot of the RCS as a function of angle (e.g., angle of incident radar signal relative to the object being detected). In detail, the device for generating a vehicle object model 10 may be operated in the flow including: obtaining a vehicle object model; applying physical property data; obtaining an RCS map; deriving requirements; and generating a vehicle object model.

In the obtaining of a vehicle object model, the 3D vehicle object model required for vehicle simulation is acquired, and in the applying of physical property data, physical property data, such as permittivity and conductivity, may be applied differently depending on the level (e.g., level of detail) of physical attribute(s) needed for each part of the vehicle object model. Permittivity may represent a characteristic of a material that indicates how easily an electric field passes through the material, and conductivity may represent a characteristic of a material that indicates how well a current may flow through the material. In the obtaining of an RCS map, an electromagnetic wave simulation reflecting the radar sensor specifications may be performed on a vehicle object model to which physical property data are applied differently for each level (e.g., level of detail) of physical attributes using an electromagnetic wave analysis tool, such as an Ansys high-frequency structure simulator (HFSS), and by this, the vehicle object RCS map according to each level of physical attributes. In the deriving of requirements, the vehicle object RCS map according to each level of physical attributes may be compared and analyzed to derive the requirement for the level of physical attributes, and in order to examine the validity of the derived requirement, the vehicle object model to which physical property data are applied differently according to each level of physical attributes may be subjected to radar sensor recognition performance simulation and the recognition time of the vehicle object may be compared. In the final generating of a vehicle object model, the vehicle object model may be generated based on the requirements for the derived level of physical attributes. For example, an object model for a passenger vehicle may be generated according to a predetermined level of physical attributes, while an object model for a commercial truck vehicle may be generated according to a different level of physical attributes than that for a passenger vehicle.

In detail, the device for generating a vehicle object model 10 may read a 3-dimension vehicle object model including parts (also referred to as components). The parts may include at least two of a body, wheel(s), lamp(s), bumper(s), and windshield(s). The 3-dimension vehicle object model including parts may be built in advance and may be loaded into a memory when the device for generating a vehicle object model 10 is operated.

Referring to FIG. 2 together, in the vehicle object model for the passenger vehicle, the body may include three parts (e.g., subcomponents), the wheel(s) may include four parts (e.g., subcomponents), the lamp(s) may include twelve parts (e.g., subcomponents), the bumper(s) may include two parts (e.g., subcomponents), and the windshield(s) may include six parts (e.g., subcomponents). For each part, a part name may be specified as shown. The above-configured vehicle object model may be required for simulation of the passenger vehicle.

Referring to FIG. 3 together, in the vehicle object model for the commercial truck vehicle, the body may include four parts, the wheel(s) may include four parts, the lamp(s) may include twelve parts, the bumper(s) may include one part, and the windshield(s) may include four parts. For each part, a part name may be specified as shown. The above-configured vehicle object model may be required for simulation of the commercial truck vehicle, and it may be seen that the part configuration is different from that of the passenger vehicle in FIG. 2.

The device for generating a vehicle object model 10 may consider physical attributes according to the level of physical attributes, which is determined at several levels, for each part that constitutes the vehicle object model. That is, the device for generating a vehicle object model 10 may consider physical attributes for the parts, and may set the level at which the physical attributes are reflected as a plurality of levels. The device for generating a vehicle object model 10 may, for example, set the level of physical attributes that applies the physical property data of a predetermined same material (e.g., metal) to the body, the wheel(s), the lamp(s), the bumper(s) and the windshield(s) in the vehicle object model for the passenger vehicle as a first level, and may set the level of physical attributes that applies the physical property data of a same predetermined material (e.g., metal) to the body, the bumper(s), and the windshield(s), applies physical property data of another material (e.g., metal and rubber) to the wheel(s), and applies physical property data of the other material (e.g., aluminum and plastic) to the lamp(s) as a second level. The device for generating a vehicle object model 10 may set the level of physical attributes that applies physical property data of a material (e.g., metal) to the body, applies physical property data of another material (e.g., metal and rubber) to the wheel(s), applies physical property data of another material (e.g., aluminum and plastic) to the lamp(s), applies physical property data of another material (e.g., plastic) to the bumper(s), and applies physical property data of another material (e.g., plastic and glass) to the windshield(s) as a third level. That is, the device for generating a vehicle object model 10 may be set so that the physical property data of one type of conductor is applied to the part at the first level, the physical property data of one type of conductor and two types of conductor and dielectric material are applied to the part at the second level, and the physical property data of one type of conductor, two types of conductor and dielectric material, and two types of dielectric material are applied to the part at the third level.

The device for generating a vehicle object model 10 may set a first level vehicle object model by applying the physical property data of the first material (e.g., metal) according to the first level among the plurality of levels to the first part (e.g., wheel(s)) from among the parts. The device for generating a vehicle object model 10 may set up a second level vehicle object model by applying the physical property data of a second material (e.g., metal and rubber) that is different from the first material (e.g., metal) according to the second level that is different from the first level from among the plurality of levels to the first part (e.g., wheel(s)).

The device for generating a vehicle object model 10 may perform an electromagnetic wave simulation on the first level vehicle object model and the second level vehicle object model to determine the level of physical attributes to be considered to the 3-dimension vehicle object model.

The device for generating a vehicle object model 10 may perform an electromagnetic wave simulation on the first level vehicle object model and the second level vehicle object model to obtain a first RCS map and a second RCS map, and may perform comparison analysis on the first RCS map and the second RCS map to determine the level of physical attribute to be considered to the 3-dimension vehicle object model. The energy reflected from an object may be dispersed in all directions, and the RCS may be quantified by measuring the intensity of the reflection in a specific direction. The reflected data may be affected by the object's size, shape, surface characteristics (e.g., material, roughness), and physical properties (e.g., permittivity and conductivity). The RCS maps may represent the data visually, showing how specific parts of an object reflect the radar signals in the 2D or 3D space.

The device for generating a vehicle object model 10 may calculate (e.g., determine) an absolute error (also referred to as absolute difference) for the first RCS map and the second RCS map, and may perform correlation analysis (e.g., on the first RCS map and the second RCS map) to derive the relevance (e.g., of the first RCS map and the second RCS map) as a numerical value (e.g., correlation value) so as to perform comparison analysis. For example, based on the absolute error and the correlation analysis, a correlation value of the first RCS map and the second RCS map may be determined. For example, the correlation value may indicate how close (e.g., closely correlated) the RCE map and the second RCS map are to each other. If the correlation analysis numerical value calculated for the first RCS map and the second RCS map is greater than or equal to a predetermined reference value (e.g., threshold value), the device for generating a vehicle object model 10 may reflect (e.g., apply) the physical attributes to the 3-dimension vehicle object model at the level of the first level vehicle object model corresponding to the first RCS map. In contrast, if the correlation analysis numerical value calculated for the first RCS map and the second RCS map is less than a reference value (e.g., threshold value), the device for generating a vehicle object model 10 may reflect the physical attribute to the 3-dimension vehicle object model at the level of the second level vehicle object model corresponding to the second RCS map.

For example, in the vehicle object model for a passenger vehicle, the comparison analysis results of the RCS map may be obtained as in Table 1 and Table 2.

TABLE 1

| | Third level | Third level | Third level |
|---|---|---|---|
| Absolute error | vs | vs | vs |
| (dBsm) | second level | first level | 0^{th} level |
| AVG | 1.83 | 5.40 | 9.97 |
| MIN | 0.00 | 0.01 | 0.03 |
| MAX | 18.27 | 25.17 | 40.15 |

TABLE 2

| | Third level | Third level | Third level |
|---|---|---|---|
| Correlation | vs | vs | vs |
| analysis | second level | first level | 0^{th} level |
| CORREL | 0.95 | 0.80 | 0.28 |

The “0^{th} level” (also referred to as level zero) may correspond to the vehicle object model provided by the simulation tool, and may indicate that no physical property data are set to be applied by the device for generating a vehicle object model 10. For the 0^{th} level, the RCS map shows a large difference (e.g., above a threshold value) from the RCS map at the third level and is not suitable for simulation. It is confirmed that the RCS map at the first level has a similar trend to the RCS map at the third level, but there is a big difference (e.g., above a threshold value) in the wheel(s) part. It is confirmed that the RCS map at the second level has the smallest absolute error (also referred to as minimum absolute difference) and the highest correlation coefficient with the RCS map at the third level. In this case, the level of physical attributes of the vehicle object model for a passenger vehicle may be set to the second level, thereby enabling efficient use of computing resources such as shortening the time of generating the vehicle object model while maintaining performance similar to the third level.

As another example, in the vehicle object model for a commercial truck vehicle, the comparison analysis results of the RCS map may be obtained as in Table 3 and Table 4.

TABLE 3

| | Third level | Third level | Third level |
|---|---|---|---|
| Absolute error | vs | vs | vs |
| (dBsm) | second level | first level | 0^{th} level |
| AVG | 1.47 | 1.91 | 14.50 |
| MIN | 0.00 | 0.00 | 0.03 |
| MAX | 16.80 | 17.05 | 37.46 |

TABLE 4

| | Third level | Third level | Third level |
|---|---|---|---|
| Correlation | vs | vs | vs |
| analysis | second level | first level | 0^{th} level |
| CORREL | 0.94 | 0.93 | −0.33 |

For the 0^{th} level, the RCS map shows a large difference from the RCS map at the third level and is not suitable for simulation. It is confirmed that both the RCS map at the first level and the RCS map at the second level have small absolute errors and high correlation coefficients with the RCS map at the third level. The level of physical attributes of the vehicle object model for a commercial truck vehicle may be set as the first level, thereby efficiently using computing resources such as shortening the time of generating a vehicle object model while maintaining performance similar to the third level.

The device for generating a vehicle object model 10 may examine validity of the vehicle object model by simulating performance of a radar sensor recognition with the vehicle object model for each level of physical attributes as a target. In detail, the device for generating a vehicle object model 10 may derive (e.g., determine) vehicle object recognition time values of a radar sensor for a first-level vehicle object model and a second-level vehicle object model, respectively, to obtain a first recognition performance value and a second recognition performance value, and may perform comparison analysis on the first recognition performance value and the second recognition performance value to verify validity of the level determination result of the physical attribute to be considered in a 3-dimension vehicle object model.

The device for generating a vehicle object model 10 may determine that it is valid to reflect the physical attribute to the 3-dimension vehicle object model at the level of the first level vehicle object model corresponding to the first recognition performance value when the absolute error mean value (also referred to as mean absolute difference) calculated for the first recognition performance value and the second recognition performance value is less than or equal to a predetermined reference value, in order to verify validity. In contrast, when the absolute error mean value calculated for the first recognition performance value and the second recognition performance value is greater than the reference value, the device for generating a vehicle object model 10 may determine that it is valid to reflect the physical attribute to the 3-dimension vehicle object model at the level of the second level vehicle object model corresponding to the second recognition performance value.

For example, the performance simulation results of radar sensor recognition may be as shown in Table 5.

TABLE 5

| | | Third level | Third level |
|---|---|---|---|
| | Absolute | vs | vs |
| Target | error | second level | first level |
| Passenger vehicle | average | 0.23 | 0.86 |
| Commercial truck | average | 0 | 0 |
| vehicle | | | |

In the case of passenger vehicles, the vehicle object recognition times of the third level and the second level are similar (e.g., below a threshold value), and the first level showed a large difference in the wheel(s) part region. Therefore, it may be concluded that the validity of setting the level of physical attributes of the vehicle object model for passenger vehicles to the second level has been verified. In the case of commercial truck vehicles, it may be confirmed that the vehicle object recognition points of the first level, second level, and third level are the same, so it may be concluded that the validity of setting the level of physical attributes of the vehicle object model for passenger vehicles to the first level has also been verified.

The device for generating a vehicle object model 10 may perform a simulation of a vehicle by considering physical attributes to a 3-dimension vehicle object model according to the level determined through the process described above.

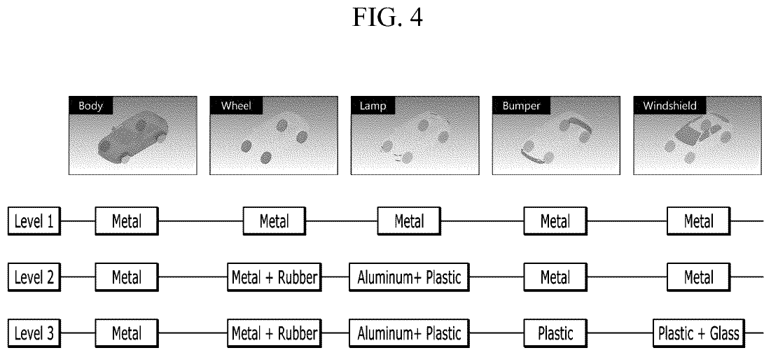

FIG. 4 shows operations of an example device for generating vehicle object models.

Referring to FIG. 4, regarding the vehicle object model for a passenger vehicle, the device for generating a vehicle object model 10 may set the level of physical attributes that applies physical property data of metal to the body, the wheel(s), the lamp(s), the bumper(s), and the windshield(s) as the first level, and may set the level of physical attributes that applies physical property data of metal to the body, the bumper(s), and the windshield(s), applies physical property data of metal and rubber to the wheel(s), and applies physical property data of aluminum and plastic to the lamp(s) as the second level. The device for generating a vehicle object model 10 may set the level of physical attributes that applies the physical property data of metal to the body, applies the physical property data of metal and rubber to the wheel(s), applies the physical property data of aluminum and plastic to the lamp(s), applies the physical property data of plastic to the bumper(s), and applies the physical property data of plastic and glass to the windshield(s) as the third level. That is, the second level may apply different physical property data to the wheel(s) and the lamp(s) compared to the first level, and the third level may apply different physical property data to the bumper(s) and the windshield(s) compared to the second level. Accordingly, the physical property data of one type of conductor may be applied to the part on the first level, the physical property data of one type of conductor and two types of conductor and dielectric material may be applied to the part on the second level, and the physical property data of one type of conductor, two types of conductor and dielectric material, and two types of dielectric materials may be applied to the part on the third level.

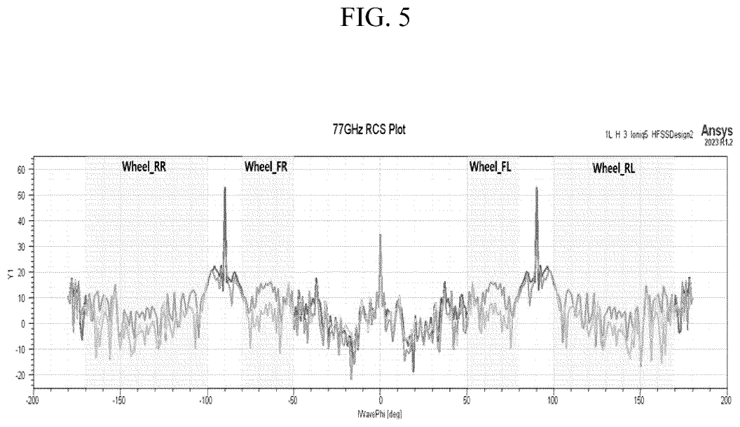

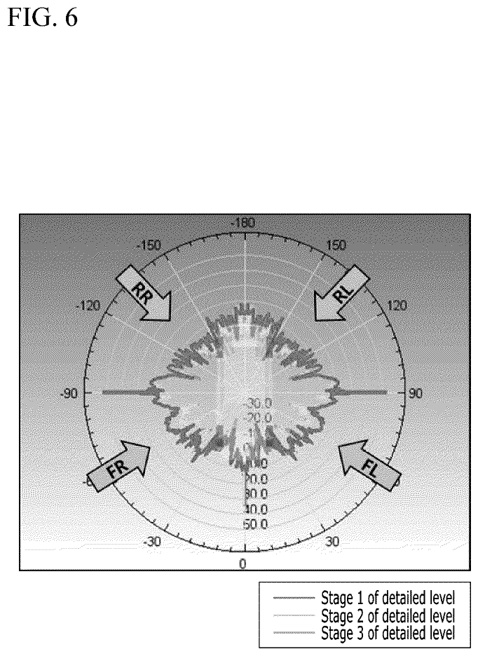

FIG. 5 and FIG. 6 show an example of an RCS map obtained by an example device for generating vehicle object models.

Referring to FIG. 5 and FIG. 6, an electromagnetic wave simulation was performed on the vehicle object model including physical attributes by using an electromagnetic wave analysis tool that is Ansys HFSS. In detail, the simulation condition may be defined based on the actual radar sensor specifications as follows, and an electromagnetic wave simulation-based RCS map for each vehicle object may be generated.

TABLE 6

| Item | Simulation parameter |
|---|---|
| Frequency | 77 GHz |
| Bandwidth | 5 GHz (76-81 GHz) |
| Horizontal/vertical measured angle | −180 to 180 deg / 90 deg |

“Detailed level 1” indicates that the level of physical attributes is set as the first level, “Detailed level 2” indicates that the level of physical attributes is set as the second level, and “Detailed level 3” indicates that the level of physical attributes is set as the third level. The results of Table 1 to Table 4 described above are data obtained under such simulation conditions.

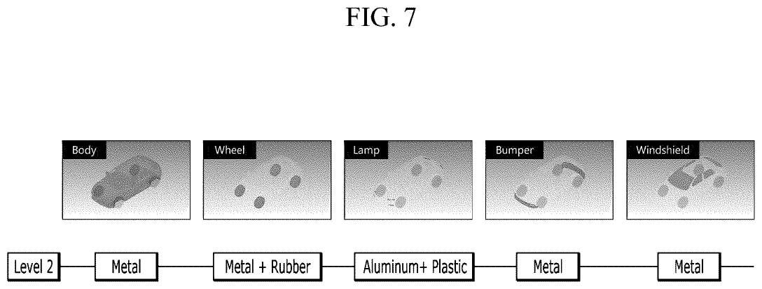

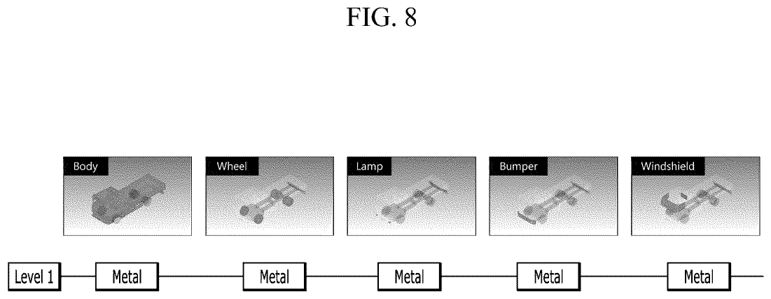

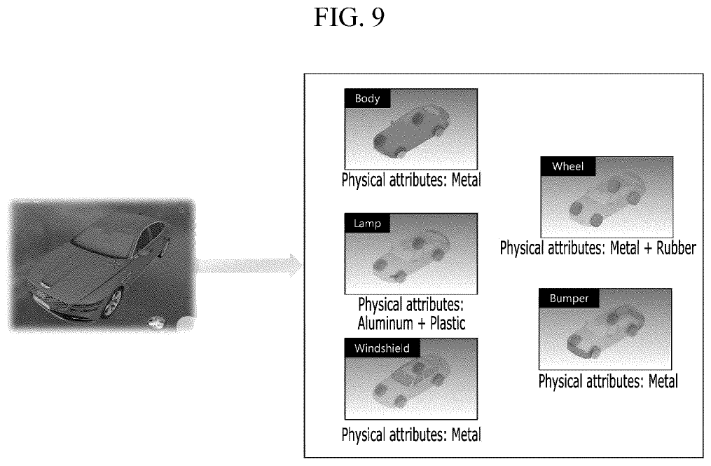

FIG. 7, FIG. 8, and FIG. 9 show operations of an example device for generating vehicle object models.

Referring to FIG. 7, it shows that the vehicle object model is generated according to the case where the level of physical attributes of the vehicle object model for a passenger vehicle is finally determined as the second level. That is, according to the second level, the vehicle object model may be generated by applying the physical property data of metal to the body, the bumper(s), and the windshield(s), applying the physical property data of metal and rubber to the wheel(s), and applying the physical property data of aluminum and plastic to the lamp(s). Referring to FIG. 9, the vehicle object model for a passenger vehicle that is actually generated is illustrated according to the second level.

Referring to FIG. 8, it shows how to generate a vehicle object model based on the level of physical attributes of the vehicle object model for a commercial truck vehicle, which is finally determined as the first level. That is, according to the first level, the vehicle object model may be generated by applying the physical property data of metal to the body, the wheel(s), the lamp(s), the bumper(s), and the windshield(s).

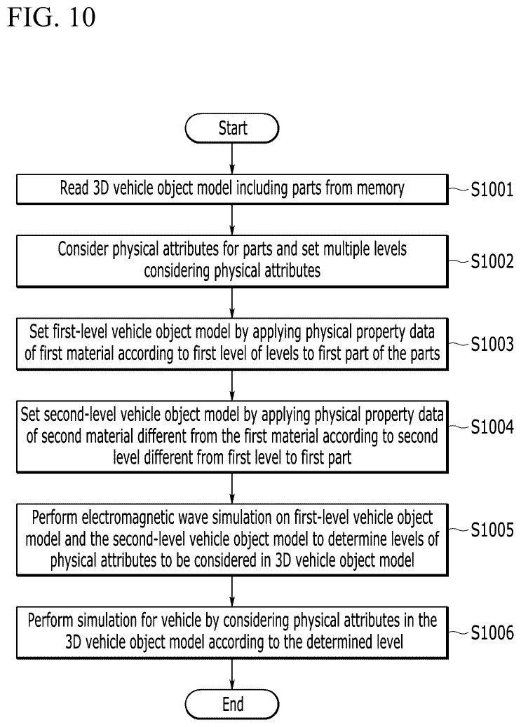

FIG. 10 shows an example method for generating vehicle object models.

Referring to FIG. 10, the vehicle object model generate method may include: reading a 3-dimension vehicle object model including parts from a memory (S1001); considering physical attributes for parts and setting a plurality of levels considering the physical attributes (S1002); setting a first-level vehicle object model by applying physical property data of a first material according to a first level of the plurality of levels for a first part of the parts (S1003); setting a second-level vehicle object model by applying physical property data of a second material that is different from the first material according to a second level of the plurality of levels that is different from the first level for the first part (S1004); performing an electromagnetic wave simulation on the first-level vehicle object model and the second-level vehicle object model to determine levels of the physical attributes to be considered in the 3-dimension vehicle object model (S1005); and performing a simulation for a vehicle by considering the physical attributes in the 3-dimension vehicle object model according to the determined level (S1006).

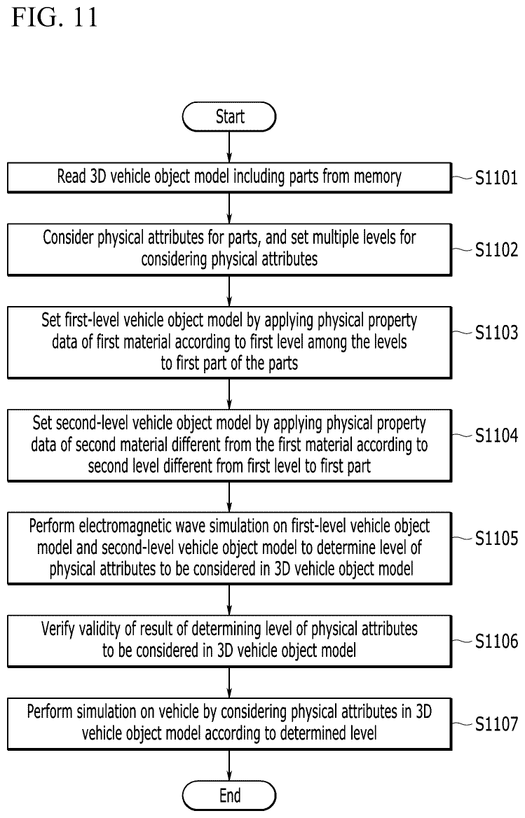

FIG. 11 shows an example method for generating vehicle object models.

Referring to FIG. 11, the method for generating a vehicle object model may include: reading a 3-dimension vehicle object model including parts from a memory (S1101); considering physical attributes for the parts, and setting a plurality of levels for considering the physical attributes (S1102); setting a first-level vehicle object model by applying physical property data of a first material according to a first level among the plurality of levels for the first part of the parts (S1103); setting a second-level vehicle object model by applying physical property data of a second material that is different from the first material according to a second level of the plurality of levels that is different from the first level for the first part (S1104); performing an electromagnetic wave simulation on the first-level vehicle object model and the second-level vehicle object model to determine a level of the physical attributes to be considered in the 3-dimension vehicle object model (S1105); verifying the validity of a result of determining the level of the physical attributes to be considered in the 3-dimension vehicle object model (S1106); and performing a simulation on the vehicle by considering the physical attributes in the 3-dimension vehicle object model according to the determined level (S1107).

The example methods shown in FIGS. 10 and 11 may be described in further detail throughout the present disclosure, and redundant descriptions may be omitted.

FIG. 12 shows an example computing device.

Referring to FIG. 12, the method and device for generating a vehicle object model may be implemented using a computing device 50. The computing device 50 may be implemented as various types of electronic devices, servers or similar devices, and their functions may be implemented through a combination of software and hardware.

The computing device 50 may include at least one of a processor 510, a memory 530, a user interface input device 540, a user interface output device 550, and a storage device 560 communicating via a bus 520. The computing device 50 may also include a network interface 570 electrically connected to the network 40. The network interface 570 may transmit or receive signals to/from other entities through the network 40.

The processor 510 may be implemented with various types of operation devices, such as a micro controller unit (MCU), an application processor (AP), a central processing unit (CPU), a graphic processing unit (GPU), a neural processing unit (NPU), and a quantum processing unit (QPU). The processor 510 is a semiconductor device for executing instructions stored in the memory 530 or the storage device 560 and may perform a core function of the system. Program codes and data stored in the memory 530 or the storage device 560 may instruct the processor 510 to perform specific tasks, thereby enabling system-wide operations. The processor 510 may be configured to implement various functions and methods described above with reference to FIG. 1 to FIG. 8.

The memory 530 and the storage device 560 may include various forms of volatile or non-volatile storage media for storing and accessing data by the system. For example, the memory 530 may include a read-only memory (ROM) 531 and a random access memory (RAM) 532. The memory 530 may be installed in the processor 510, and in this case, the data transmission rate between the memory 530 and the processor 510 may be very fast. The memory 530 may be disposed outside the processor 510, and the memory 530 may be connected to the processor 510 through various data buses or interfaces. This connection may be made through a variety of known means, for example, the peripheral component interconnect express (PCIe) interface for high-rate data transmission or through a memory controller.

At least some components or functions of the method and device for generating a vehicle object model may be implemented as a program or software executed on the computing device 50, and the program or software may be stored on a computer-readable recording medium or storage medium. In detail, the computer-readable recording medium or storage medium may record a program for causing a computer including a processor 510 for executing the program or instructions stored in the memory 530 or the storage device 560 to execute stages included in implementing the method and device for generating a vehicle object model.

At least some components or functions of the method and device for generating a vehicle object model may be implemented using hardware or circuitry of the computing device 50, or may be implemented as separate hardware or circuitry electrically connected to the computing device 50.

At least one non-transitory computer-readable medium including instruction executable by the computing device 50 may be provided, and the instructions may allow the computing device 50 to perform operations when executed by at least one processor of the computing device 50. The operations may include the configurations, functions, stages, etc. described in this specification on the method and device for generating vehicle object models.

The present disclosure provides a device for generating a vehicle object model including: at least one non-transitory computer readable medium including instructions; and at least one processor for performing operations by executing the instructions, wherein the operations include reading a 3-dimension vehicle object model including parts from the medium, considering physical attributes for the parts, and setting a plurality of levels for considering the physical attributes, setting a first level vehicle object model on a first part of the parts by applying physical property data of a first material according to a first level of the plurality of levels, setting a second level vehicle object model on the first part by applying physical property data of a second material that is different from the first material according to a second level of the plurality of levels that is different from the first level, and determining the level of the physical attribute to be considered in the 3-dimension vehicle object model by performing an electromagnetic wave simulation on the first level vehicle object model and the second level vehicle object model.

The determining of the level of the physical attribute may include obtaining a first radar cross section (RCS) map and a second RCS map by performing an electromagnetic wave simulation on the first level vehicle object model and the second level vehicle object model, and performing a comparison analysis on the first RCS map and the second RCS map to determine the level of the physical attribute to be considered in the 3-dimension vehicle object model.

The performing of a comparison analysis may include calculating an absolute error on the first RCS map and the second RCS map, performing a correlation analysis, and deriving relevance as a numerical value.

The performing of a comparison analysis may further include when the correlation analysis numerical value calculated on the first RCS map and the second RCS map is equal to or greater than a predetermined reference value, considering the physical attribute in the 3-dimension vehicle object model at the level of the first level vehicle object model corresponding to the first RCS map.

The performing of a comparison analysis may further include, when the correlation analysis numerical value calculated on the first RCS map and the second RCS map is less than the reference value, considering the physical attribute in the 3-dimension vehicle object model at the level of the second level vehicle object model corresponding to the second RCS map.

The operation may further include obtaining a first recognition performance value and a second recognition performance value by respectively deriving vehicle object recognition time values of a radar sensor on the first level vehicle object model and the second level vehicle object model, and verifying validity of level determination results of physical attributes to be considered in the 3-dimension vehicle object model by performing a comparison analysis on the first recognition performance value and the second recognition performance value.

The verifying of validity may include, when an absolute error mean value calculated on the first recognition performance value and the second recognition performance value is equal to or less than a predetermined reference value, determining that it is valid to consider physical attributes in the 3-dimension vehicle object model at the level of the first level vehicle object model corresponding to the first recognition performance value.

The verifying of validity may further include, when the absolute error mean value calculated on the first recognition performance value and the second recognition performance value is equal to or less than the reference value, determining that it is valid to consider physical attributes in the 3-dimension vehicle object model at the level of the second level vehicle object model corresponding to the second recognition performance value.

The parts may include a body, a wheel, a lamp, a bumper, and a windshield.

The present disclosure provides a method for generating a vehicle object model for simulating vehicles performed by a computing device including a processor and a memory including: reading, by the processor, a 3-dimension vehicle object model including parts from the memory; considering, by the processor, physical attributes for the parts, and setting a plurality of levels for considering the physical attributes; setting, by the processor, a first level vehicle object model on a first part of the parts by applying physical property data of a first material according to a first level of the plurality of levels; setting, by the processor, a second level vehicle object model on the first part by applying physical property data of a second material that is different from the first material according to a second level of the plurality of levels that is different from the first level; and determining, by the processor, the level of the physical attribute to be considered in the 3-dimension vehicle object model by performing an electromagnetic wave simulation on the first level vehicle object model and the second level vehicle object model.

The determining of the level of the physical attribute may include obtaining, by the processor, a first radar cross section (RCS) map and a second RCS map by performing an electromagnetic wave simulation on the first level vehicle object model and the second level vehicle object model, and performing, by the processor, a comparison analysis on the first RCS map and the second RCS map to determine the level of the physical attribute to be considered in the 3-dimension vehicle object model.

The performing of a comparison analysis may include calculating, by the processor, an absolute error on the first RCS map and the second RCS map, performing a correlation analysis, and deriving relevance as a numerical value.

The performing of a comparison analysis may further include, when the correlation analysis numerical value calculated on the first RCS map and the second RCS map is equal to or greater than a predetermined reference value, considering, by the processor, the physical attribute in the 3-dimension vehicle object model at the level of the first level vehicle object model corresponding to the first RCS map.

The performing of a comparison analysis may further include, when the correlation analysis numerical value calculated on the first RCS map and the second RCS map is less than the reference value, considering, by the processor, the physical attribute in the 3-dimension vehicle object model at the level of the second level vehicle object model corresponding to the second RCS map.

The method may further include obtaining, by the processor, a first recognition performance value and a second recognition performance value by respectively deriving vehicle object recognition time values of a radar sensor on the first level vehicle object model and the second level vehicle object model, and verifying, by the processor, validity of level determination results of physical attributes to be considered in the 3-dimension vehicle object model by performing a comparison analysis on the first recognition performance value and the second recognition performance value.

The verifying of validity may include, when an absolute error mean value calculated on the first recognition performance value and the second recognition performance value is equal to or less than a predetermined reference value, determining, by the processor, that it is valid to consider physical attributes in the 3-dimension vehicle object model at the level of the first level vehicle object model corresponding to the first recognition performance value.

The verifying of validity may further include, when the absolute error mean value calculated on the first recognition performance value and the second recognition performance value is equal to or less than the reference value, determining, by the processor, that it is valid to consider physical attributes in the 3-dimension vehicle object model at the level of the second level vehicle object model corresponding to the second recognition performance value.

The parts may include a body, a wheel, a lamp, a bumper, and a windshield.

The method may further include performing a simulation on the vehicle by considering physical attribute in the 3-dimension vehicle object model according to the determined level.

The present disclosure provides a non-transitory computer readable medium including instructions executable by a computing device, wherein the instructions allow the computing device to perform operations when executed by at least one processor of the computing device, and the operations include reading a 3-dimension vehicle object model including parts from a memory of the computing device, considering physical attributes for the parts and setting a plurality of levels for considering the physical attributes, setting a first level vehicle object model on a first part of the parts by applying physical property data of a first material according to a first level of the plurality of levels, setting a second level vehicle object model on the first part by applying physical property data of a second material that is different from the first material according to a second level of the plurality of levels that is different from the first level, and determining the level of the physical attribute to be considered in the 3-dimension vehicle object model by performing an electromagnetic wave simulation on the first level vehicle object model and the second level vehicle object model.

The conditions required for generating a vehicle object model DB may be derived through comparison analysis on the RCS Map for object models at each physical attribute-based detailed level, and a reference of a method for generating an object model that may be utilized for virtual simulation may be presented based on this. By the process for generating an object model DB, an object model including the same physical characteristics for each simulation tool chain may be generated. This may ensure consistency in the simulation environment when different simulation tool chains are used for respective sensors. In addition, it derives and simplifies the conditions required for generating the vehicle object model DB to thus provide the effect of reducing the time of generating an object model. Furthermore, the accuracy and efficiency of evaluating simulation may be improved by obtaining the reliability of the physical attribute-based vehicle object model required for physics-based sensor simulation.

While one or more example embodiments of the present disclosure have been described in detail, it is to be understood that the disclosure is not limited to the disclosed example embodiments, but on the contrary, is intended to cover various modifications and equivalent arrangements included within the spirit and scope of the appended claims.

What is claimed is:

1. A device comprising:
a processor; and
a memory storing a three-dimensional vehicle object model of a vehicle, the three-dimensional vehicle object model comprising a plurality of components of the vehicle,
wherein the memory further stores at least one instruction that is configured, when executed by the processor communicating with the memory, to cause the device to:
obtain, from the memory, the three-dimensional vehicle object model;
determine, based on the three-dimensional vehicle object model and physical attributes of the plurality of components:
a first level vehicle object model by applying first physical property data of a first material to at least one component of the plurality of components of the three-dimensional vehicle object model; and
a second level vehicle object model by applying second physical property data of a second material, that is different from the first material, to the at least one component; and
perform, on at least one of the first level vehicle object model or the second level vehicle object model, an electromagnetic wave simulation to determine a level of physical attributes to be applied to the three-dimensional vehicle object model.

2. The device of claim 1, wherein the at least one instruction is configured, when executed by the processor communicating with the memory, to cause the device to perform the electromagnetic wave simulation by:
obtaining, based on performing the electromagnetic wave simulation on the first level vehicle object model, a first radar cross section (RCS) map associated with the vehicle; and
obtaining, based on performing the electromagnetic wave simulation on the second level vehicle object model, a second RCS map associated with the vehicle, and
wherein the at least one instruction is configured, when executed by the processor communicating with the memory, to further cause the device to determine the level of physical attributes based on a comparison between the first RCS map and the second RCS map.

3. The device of claim 2, wherein the at least one instruction is configured, when executed by the processor communicating with the memory, to further cause the device to perform the comparison by:
determining an absolute difference between the first RCS map and the second RCS map;
performing a correlation analysis on each of the first RCS map and the second RCS map; and
determining, based on the absolute difference and the correlation analysis, a correlation value of the first RCS map and the second RCS map.

4. The device of claim 3, wherein the at least one instruction is configured, when executed by the processor communicating with the memory, to further cause the device to determine the level of physical attributes by:
selecting, based on the correlation value being greater than or equal to a threshold value, a level associated with the first level vehicle object model corresponding to the first RCS map.

5. The device of claim 3, wherein the at least one instruction is configured, when executed by the processor communicating with the memory, to further cause the device to determine the level of physical attributes by:
selecting, based on the correlation value being less than a threshold value, a level associated with the second level vehicle object model corresponding to the second RCS map.

6. The device of claim 1, wherein the at least one instruction is configured, when executed by the processor communicating with the memory, to cause the device to perform the electromagnetic wave simulation by:
determining, based on a first recognition time by a radar sensor on the first level vehicle object model, a first recognition performance value;
determining, based on a second recognition time by the radar sensor on the second level vehicle object model, a second recognition performance value; and
verifying, based on a comparison between the first recognition performance value and the second recognition performance value, validity of the determined level of physical attributes.

7. The device of claim 6, wherein the at least one instruction is configured, when executed by the processor communicating with the memory, to cause the device to verify the validity by:
determining, based on a mean absolute difference between the first recognition performance value and the second recognition performance value being less than or equal to a threshold value, that the determined level of physical attributes is valid.

8. The device of claim 6, wherein the at least one instruction is configured, when executed by the processor communicating with the memory, to cause the device to verify the validity by:
determining, based on a mean absolute difference between the first recognition performance value and the second recognition performance value being greater than a threshold value, that the determined level of physical attributes is valid.

9. The device of claim 1, wherein the plurality of components comprise at least one of a body, a wheel, a lamp, a bumper, and a windshield.

10. A method performed by a computing device, the method comprising:
obtaining, by a processor of the computing device, a three-dimensional vehicle object model of a vehicle, wherein the three-dimensional vehicle object model comprises a plurality of components of the vehicle;
determining, based on the three-dimensional vehicle object model and physical attributes of the plurality of components:
a first level vehicle object model by applying first physical property data of a first material to at least one component of the plurality of components of the three-dimensional vehicle object model; and
a second level vehicle object model by applying second physical property data of a second material, that is different from the first material, to the at least one component; and
performing, on at least one of the first level vehicle object model or the second level vehicle object model, an electromagnetic wave simulation to determine a level of physical attributes to be applied to the three-dimensional vehicle object model.

11. The method of claim 10, wherein the performing of the electromagnetic wave simulation comprises:
obtaining, based on performing the electromagnetic wave simulation on the first level vehicle object model, a first radar cross section (RCS) map associated with the vehicle; and
obtaining, based on performing the electromagnetic wave simulation on the second level vehicle object model, a second RCS map associated with the vehicle, and
wherein the method further comprises:
determining the level of physical attributes based on a comparison between the first RCS map and the second RCS map.

12. The method of claim 11, further comprising performing the comparison by:
determining an absolute difference between the first RCS map and the second RCS map;
performing a correlation analysis on each of the first RCS map and the second RCS map; and
determining, based on the absolute difference and the correlation analysis, a correlation value of the first RCS map and the second RCS map.

13. The method of claim 12, further comprising:
selecting, based on the correlation value being greater than or equal to a threshold value, a level associated with the first level vehicle object model corresponding to the first RCS map.

14. The method of claim 12, further comprising:
selecting, based on the correlation value being less than a threshold value, a level associated with the second level vehicle object model corresponding to the second RCS map.

15. The method of claim 10, wherein the performing of the electromagnetic wave simulation comprises:
determining, based on a first recognition time by a radar sensor on the first level vehicle object model, a first recognition performance value;
determining, based on a second recognition time by the radar sensor on the second level vehicle object model, a second recognition performance value; and
verifying, based on a comparison between the first recognition performance value and the second recognition performance value, validity of the determined level of physical attributes.

16. The method of claim 15, wherein the verifying of the validity comprises:
determining, based on a mean absolute difference between the first recognition performance value and the second recognition performance value being less than or equal to a threshold value, that the determined level of physical attributes is valid.

17. The method of claim 15, wherein the verifying of the validity comprises:
determining, based on a mean absolute difference between the first recognition performance value and the second recognition performance value being greater than a threshold value, that the determined level of physical attributes is valid.

18. The method of claim 10, wherein the plurality of components comprise at least one of a body, a wheel, a lamp, a bumper, and a windshield.

19. The method of claim 10, further comprising:
performing, based on applying the determined level of physical attributes to the three-dimensional vehicle object model, a simulation on the vehicle.

20. A non-transitory computer-readable medium storing instructions that, when executed by a computing device, cause the computing device to:
obtain a three-dimensional vehicle object model of a vehicle, wherein the three-dimensional vehicle object model comprises a plurality of components of the vehicle;
determine, based on the three-dimensional vehicle object model and physical attributes of the plurality of components:
a first level vehicle object model by applying first physical property data of a first material to at least one component of the plurality of components of the three-dimensional vehicle object model; and
a second level vehicle object model by applying second physical property data of a second material, that is different from the first material, to the at least one component; and
performing, on at least one of the first level vehicle object model or the second level vehicle object model, an electromagnetic wave simulation to determine a level of physical attributes to be applied to the three-dimensional vehicle object model.
